(19) United States
(12) Patent Application Publication
(10) Pub. No.: US 2017/0148518 A1
(43) Pub. Date: May 25, 2017

(54) SEMICONDUCTOR MEMORY DEVICE

(71) Applicant: KABUSHIKI KAISHA TOSHIBA, Tokyo (JP)

(72) Inventor: Takuya KADOWAKI, Chigasaki Kanagawa (JP)

(73) Assignee: KABUSHIKI KAISHA TOSHIBA, Tokyo (JP)

(21) Appl. No.: 15/262,771

(22) Filed: Sep. 12, 2016

(30) Foreign Application Priority Data
Nov. 25, 2015 (JP) 2015-229837

(51) Int. Cl. G11C 16/10; G11C 16/16; G11C 16/08; G11C 16/04; G11C 16/26

(52) U.S. Cl. CPC G11C 16/10; G11C 16/0483; G11C 16/26; G11C 16/08; G11C 16/16

(57) ABSTRACT

According to one embodiment, a semiconductor memory device includes: first and second memory cell transistors; first and second bit lines; a first sense amplifier capable of coupling the first bit line to one of first and second power supply lines; and a second sense amplifier capable of coupling the second bit line to one of the first and second power supply lines. A write operation includes first and second steps. In the first step, when the second bit line is uncoupled from the first and second power supply line, the first sense amplifier applies a third voltage to the first bit line. In the second step, when the first bit line is uncoupled from the first and second power supply line, the second sense amplifier applies the second voltage to the second bit line.

### CROSS-REFERENCE TO RELATED APPLICATIONS

This application is based upon and claims the benefit of priority from Japanese Patent Application No. 2015-229837, filed Nov. 25, 2015, the entire contents of which are incorporated herein by reference.

### FIELD

Embodiments described herein relate generally to a semiconductor device.

### BACKGROUND

NAND flash memory is known as a semiconductor memory device.

### BRIEF DESCRIPTION OF THE DRAWINGS

FIG. 1 is a block diagram of a semiconductor memory device according to a first embodiment;

FIG. 2 is a circuit diagram of a sense amplifier unit in the semiconductor memory device according to the first embodiment;

FIG. 3 is a conceptual diagram of a write operation in the semiconductor memory device according to the first embodiment;

FIG. 4 is a timing chart illustrating potentials of interconnects during the write operation in the semiconductor memory device according to the first embodiment;

FIG. 5 is a diagram illustrating the potentials of the interconnects during the write operation according to the first embodiment;

FIG. 6 is a diagram illustrating the potentials of the interconnects during the write operation according to the first embodiment;

FIG. 7 is a diagram illustrating the potentials of the interconnects during the write operation according to the first embodiment;

FIG. 8 is a conceptual diagram of a write operation in a semiconductor memory device according to a second embodiment;

FIG. 9 is a timing chart illustrating potentials of interconnects during the write operation in the semiconductor memory device according to the second embodiment;

FIG. 10 is a diagram illustrating the potentials of the interconnects during the write operation in the semiconductor memory device according to the second embodiment; and

FIG. 11 is a diagram illustrating the potentials of the interconnects during the write operation in the semiconductor memory device according to the second embodiment.

### DETAILED DESCRIPTION

In general, according to one embodiment, a semiconductor memory device includes: a first memory string including a first memory cell transistor; a second memory string including a second memory cell transistor; a word line coupled both to a gate of the first memory cell transistor and to a gate of the second memory cell transistor; a first bit line coupled to the first memory string; a second bit line coupled to the second memory string; a first sense amplifier capable of coupling The first bit line to one of a first power supply line to which a first voltage is applied and a second power supply line to which a second voltage lower than the first voltage is applied; and a second sense amplifier capable of coupling the second bit line to one of the first and second power supply lines. A write operation includes first and second steps. In the first step, when the second bit line is uncoupled from the first and second power supply lines, the first sense amplifier applies a third voltage higher than the second voltage and lower than or equal to the first voltage to the first bit line. In the second step, when the first bit line is uncoupled from the first and second power supply lines, the second sense amplifier applies the second voltage to the second bit line.

### 1. First Embodiment

A semiconductor memory device according to a first embodiment will be described. As an example of a semi conductor memory device, a planar NAND flash memory will be described in which memory cell transistors are two-dimensionally arranged on a semiconductor substrate.

1.1 Configuration

1.1.1 General Configuration of the Semiconductor Memory Device

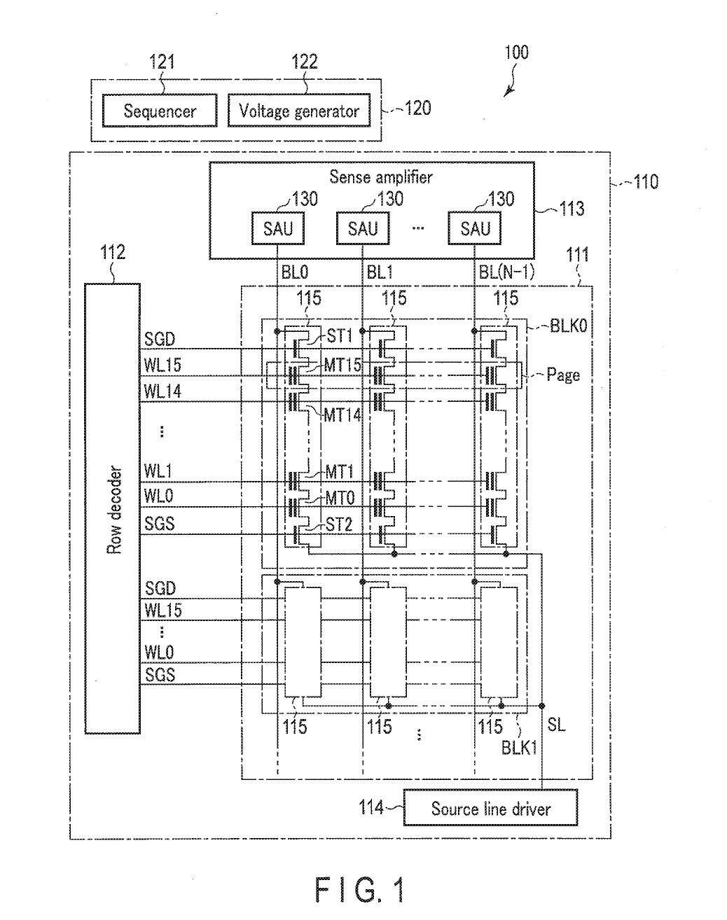

First, a general configuration of the semiconductor memory device will be described using FIG. 1. As depicted in FIG. 1, a NAND flash memory 100 generally includes a core portion 110 and a peripheral circuit 120.

The core portion 110 includes a memory cell array 111, a row decoder 112, a sense amplifier 113, and a source line driver 114.

The memory cell array 111 comprises a plurality of blocks BLK (BLK0, BLK1, . . . ) each of which is a set of a plurality of nonvolatile memory cell transistors. Data in the same block BLK is, for example, erased at a time.

Each of the blocks BLK includes a plurality of NAND strings 115, and each of the NAND strings 115 includes a plurality of memory cell transistors MT coupled together in series. The memory cell transistors MT are two-dimensionally arranged on the semiconductor substrate. Any number of NAND strings 115 are included in one block BLK.

Each of the NAND strings 115 includes, for example, 16 memory cell transistors (MT0 to MT15) and select transistors ST1 and ST2. The memory cell transistor MT comprises a stack gate including a control gate and a charge storage layer, to hold data in a nonvolatile manner. The memory cell transistor MT may be of a MONOS type in which an insulating film is used as the charge storage layer or an FG type in which a conductive film is used as a the charge storage layer. Moreover, the number of the memory cell transistors MT is not limited to 16 but may be 8, 32, 64, 128, or the like. The number is not limited.

In the present embodiment, the memory cell transistor can hold 1-bit data, that is, either “1” data or “0” data. In the present embodiment, a state where the memory cell transistor MT holds “1” data is defined as a state where substantially no charge has been injected into the charge storage layer. On the other hand, a state where the memory cell transistor holds “0” data is defined as a state where charge has been injected into the charge storage layer. Therefore, a memory cell transistor MT holding “1” data has a lower threshold voltage than a memory cell transistor MT holding “0” data. A relation between the data and the threshold level is not limited to the above-described relation and may be changed as needed. The memory cell transistor MT may hold data of 2 bits or more.

Electric paths in the memory cell transistors MT0 to MT15 in one NAND string 115 are coupled together in series. A drain of the memory cell transistor MT15, located at one end of the series coupled electric paths, is coupled to a source of the select transistor ST2. A source of the memory cell transistor MT0, located at the other end of the series coupled electric paths, coupled to a drain of the select transistor ST2.

Gates of the select transistors ST1 in the same block BLK are all coupled to the same select gate line SGD. In an example in FIG. 1, the gates of the select transistors ST1 in the block BLK0 are all coupled to a select gate line SGD0. Gates of the select transistors ST1 in the block BLK1, not depicted in the drawings, are all coupled to a select gate line SGD1. Similarly, gates of the select transistors ST2 in the same block BLK are all coupled to the same select gate line SGS.

Control gates of the memory cell transistors MT0 to MT15 in the same block BLK are coupled to different word lines WL0 to WL15, respectively. For the NAND strings 115 arranged in a matrix in the memory cell array 111, drains of the select transistors ST1 in the NAND strings 115 in the same row are coupled to different bit lines BL(BL0 to BL(N−1), (N−1) is a natural number of 1 or more), respectively. Drains of the select transistors ST1 in the NAND strings 115 in the same column are coupled to one of the bit lines BL0 to BL(N−1). That is, each of the bit lines BL allows the NAND strings 115 in a plurality of blocks BLK to be all coupled to the bit line. Sources of the select transistors ST2 in each block BLK are all coupled to a source line SL. That is, the source line SL, for example, allows the NAND strings 115 in a plurality of blocks BLK to be all coupled the source line SL.

For example, during data write or read, the row decoder 112 decodes a block address or a page address to select a word line WL corresponding to a target page. The row decoder 112 then applies appropriate voltages to a selected word line WL, unselected word lines WL, and the select gate lines SGD and SGS.

The sense amplifier 113 includes a plurality of sense amplifier units 130. The sense amplifier units 130 are provided in association with the respective bit lines BL. During data read, the sense amplifier unit 130 senses and amplifies data read onto the corresponding bit line BL from the corresponding memory cell transistor MT. During data write, the sense amplifier unit 130 transfers write data to the memory cell transistor MT. Each of the sense amplifier units 130 includes a latch circuit which allows data to be held. The sense amplifier unit 130 will be described below in detail.

During write, read, and erasure, the source line driver 114 applies a needed voltage to the source line SL.

The peripheral circuit 120 includes a sequencer 121 and a voltage generator 122.

The sequencer 121 controls operation of the NAND flash memory 100 as a whole.

The voltage generator 122 generates voltages needed for data write, read, and erasure to apply the resultant voltages to the row decoder 112, the sense amplifier 113, and the source line driver 114. The row decoder 112, the sense amplifier 113, and the source line driver 114 apply voltages supplied by the voltage generator 122 to the memory cell transistors MT.

In the description of the present example, the memory cell transistors MT are two-dimensionally arranged on the semiconductor substrate. However, the memory cell transistors MT may be three-dimensionally stacked over the semiconductor substrate.

A configuration of the memory cell array 111 in a three-dimensional stacked flash memory is described in, for example, U.S. patent application Ser. No. 12/407,403 entitled “THREE DIMENSIONAL STACKED NONVOLATILE SEMICONDUCTOR MEMORY” filed on Mar. 19, 2009. Configurations of the memory cell array 111 in a three-dimensional stacked flash memory are also described in U.S. patent application Ser. No. 12/406,524 entitled “THREE DIMENSIONAL STACKED NONVOLATILE SEMICONDUCTOR MEMORY” filed on Mar. 18, 2009, U.S. patent application Ser. No. 12/679,991 entitled “NON-VOLATILE SEMICONDUCTOR STORAGE DEVICE AND METHOD OF MANUFACTURING THE SAME” filed on Mar. 25, 2010, and U.S. patent application Ser. No. 12/532, 030 entitled “SEMICONDUCTOR MEMORY AND METHOD FOR MANUFACTURING SAME” filed on Mar. 23, 2009. These patent applications are incorporated herein in their entireties by reference.

Moreover, a range for data erasure is not limited to one block BLK. A plurality of blocks BLK may be erased at a time or a partial area in one block BLK may be erased at a time.

Data erasure is described in U.S. patent application Ser. No. 12/694,690 entitled “NON-VOLATILE SEMICONDUCTOR STORAGE DEVICE” filed on Jan. 27, 2010. Data erasure is described in U.S. patent application Ser. No. 13/235,389 entitled “NONVOLATILE SEMICONDUCTOR MEMORY DEVICE” filed on Sep. 18, 2011. These patent applications are incorporated herein in their entireties by reference.

1.1.2 Sense Amplifier

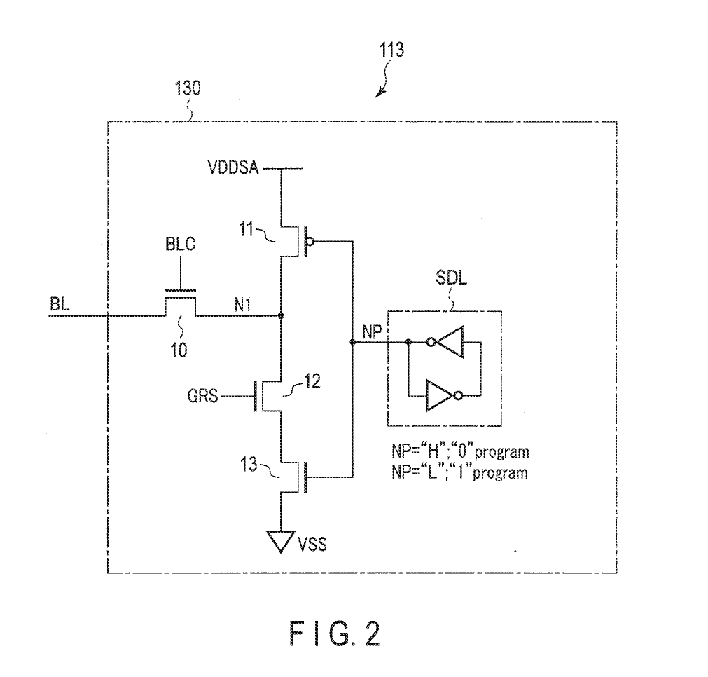

Now, a configuration of the sense amplifier 113 will be described using FIG. 2. For simplification of description, FIG. 2 depicts a part of the circuit in the sense amplifier unit 130 which is needed for a write operation. In the present embodiment, the sense amplifier 113 based on a current sensing scheme in which a current flowing through the bit line BL is sensed will be described by way of example. However, a sense amplifier based on a voltage sensing scheme may be used.

In the current sensing scheme in the present, embodiment, data is read at a time from the memory cell transistors MT coupled to one of the word lines WL in one of the blocks BLK (this unit is referred to as a “page”). Therefore, the sense amplifier 113 according to the present embodiment comprises the sense amplifier unit 130 depicted in FIG. 2, for each bit line BL.

As depicted in FIG. 2, the sense amplifier unit 130 includes n-channel MOS transistors 10, 12, and 13, a p-channel MOS transistor 11, and a latch circuit SDL.

A signal BLC is input to a gate of the transistor 10. One of a source and a drain of the transistor 10 is coupled to the corresponding bit line BL and the other is coupled to a node N1. The transistor 10 is configured to clamp the voltage of the corresponding bit line BL to a voltage corresponding to the signal BLC. That is, the bit line BL is subjected to a voltage value (hereinafter referred to as a “clamp voltage”) resulting from subtraction of a threshold voltage Vt10 for the transistor 10 from the voltage of the signal BLC.

A gate of the transistor 11 is coupled to a node NP, and one of a source and a drain of the transistor 11 is coupled to a power supply voltage line. Through the power supply voltage line, a voltage VDDSA is provided to the transistor 11. The other of the source and the drain of the transistor 11 is coupled to the node N1.

A signal GRS is input to a gate of the transistor 12. One of a source and a drain of the transistor 12 is coupled to the node N1, and the other is coupled to one of a source and a drain of the transistor 13.

A gate of the transistor 13 is coupled to the node NP. The other of the source and the drain of the transistor 13 is coupled to a ground voltage line (a voltage VSS is applied to the transistor 13). Therefore, the transistors 11 and 13 serve as a switch circuit which applies the voltage VDDSA or the voltage VSS to the node N1 depending on the voltage of the node NP.

The latch circuit SDL includes two inverters, and an input terminal of each of the inverters is coupled to an output terminal of the other inverter. During a write operation, the latch circuit SDL internally holds external input data. When the held data is at an “H” level, that is, the node NP is at the “H” level, “0” data is written to the memory cell transistor MT. When the held data is at an “L” level, that is, the node NP is at the “L” level, “1” data is written to the memory cell transistor MT. FIG. 2 depicts only one latch circuit, but a plurality of latch circuits may be provided. For example, if each memory cell transistor MT holds data of 2 bits or more, a plurality of latch circuits is provided.

1.2 Data Write Operation

Now, a data write operation according to the present embodiment will be described.

1.2.1 Concept of the Data Write Operation according to the Present Embodiment

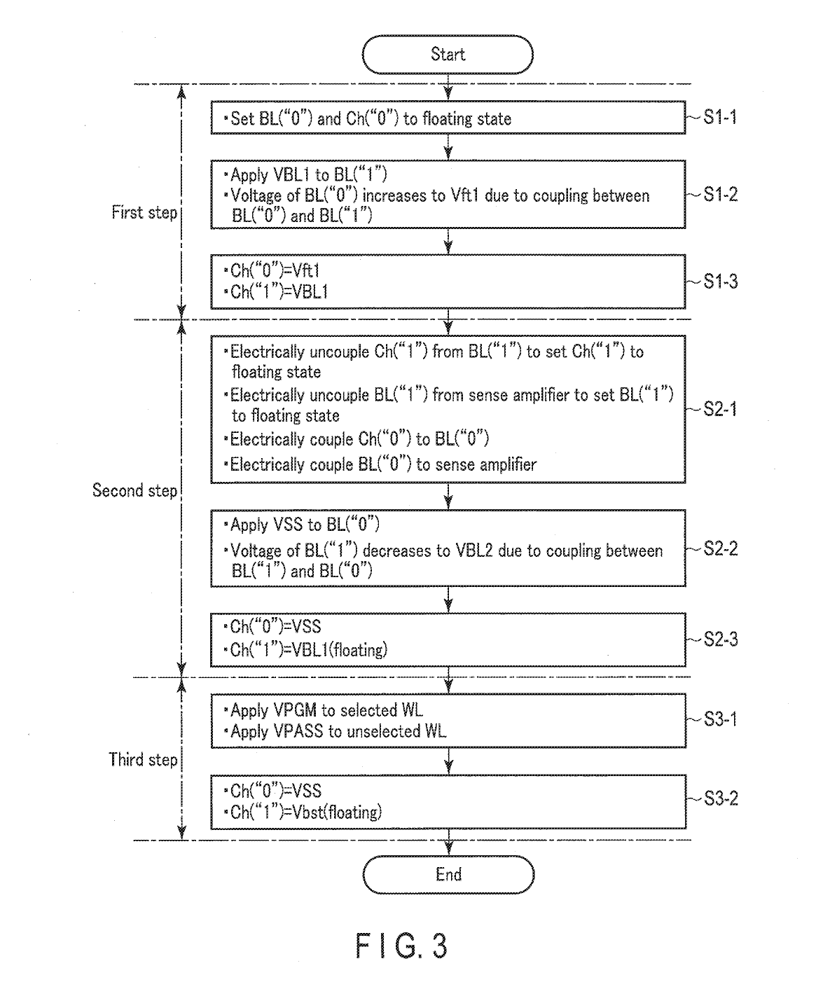

First, the concept of a write operation will be described using FIG. 3, particularly with the potentials of the bit lines BL and channels focused on. The write operation in the present embodiment generally includes three steps (first to third steps). A channel for the NAND string 115 including the memory cell transistors MT to which “0” data is written is referred to as “Ch(“0”)”, and the corresponding bit line is referred to as “BL(“0”)”. A channel for the NAND string 115 including the memory cell transistors MT to which “1” data is written is referred to as “Ch(“1”)”, and the corresponding bit line is referred to as “BL(“1”)”.

<First Step>

In a first step, the sense amplifier 113 sets the bit line BL(“0”) to a floating state, and applies a positive voltage VBL1 to the bit line BL(“1”). The voltage VBL1 is a positive voltage applied to the bit line BL(“1”) in order to raise the potential of channel Ch(“1”) and is higher than a voltage applied to the bit line BL(“0”).

More specifically, first, with the bit line BL(“0”) and the channel Ch(“0”) electrically coupled together, the sequencer 121 sets the bit line BL(“0”) and the channel Ch(“0”) to the floating state (step S1-1).

In this state, the sense amplifier 113 applies the voltage VBL1 to the bit line BL(“1”). At this time, since the bit line BL(“0”) is in the floating state”, the voltage of the bit line (“0”) increases due to the coupling between the bit line BL(“0”) and the bit line BL(“1”) (this voltage is hereinafter referred to as “Vft1”) (step S1-2).

The NAND string 115 in the selected block ELK is electrically coupled to the bit lines BL, and thus, the potentials of the bit lines FL are transferred to the channels Ch. Therefore, the voltage of the channel Ch(“0”) is set to Vft1, and the voltage of the channel Ch(“1”) is set to VBL1 (step S1-3).

<Second Step>

In a second step, the sense amplifier 113 sets the bit line BL(“1”) to the floating state, and applies the voltage VSS to the bit line BL(“0”).

More specifically, first, the sequencer 121 electrically uncouple the channel Ch(“1”) and the bit line (“1”) from each other, and sets the channel Ch(“1”) to the floating state. Moreover, the sequencer 121 electrically uncouple the bit line BL(“1”) and the sense amplifier 113 from each other, and sets the bit line BL(“1”) to the floating state. On the other handy the sequencer 121 electrically couples the channel Ch(“0”), the bit line BL(“0”) and the sense amplifier 113 together (step S2-1).

In this state, the sense amplifier 113 applies the voltage VSS to the bit line BL(“0”). At this time, the bit line BL(“1”) is in the floating state, and thus, the voltage of the bit line BL(“1”) decreases from VBL1 due to the coupling between the bit line BL(“1”) and the bit line BL(“0”) (in the following description, when the voltage of the bit line BL(“1”) at this time is designated as the “voltage VBL2”, VBL1>VBL2) (step S2-2).

The channel Ch(“0”) and the bit line BL(“0”) are electrically coupled together, and thus, the voltage of the channel Ch(“0”) is at VSS. On the other hand, the channel Ch(“1”) is electrically uncoupled from the bit line BL(“1”) and is thus in the floating state. Consequently, the voltage of the channel Ch(“1”) is kept at VBL1 (step S2-3).

<Third Step>

In a third step, a voltage is applied to the word line WL to write data to the memory cell transistor MT.

More specifically, the row decoder 112 applies a program voltage VPGM to a selected word line WL, while applying a voltage VPASS to unselected word lines WL (step S3-1). At this time, the voltage of the channel Ch(“0”) is kept at VSS, whereas the voltage of the channel Ch(“1”) increases (the voltage at this time is hereinafter referred to as “Vbst”) due to coupling between the channel Ch(“1”) and the word line WL (step S3-2). Consequently, electrons are injected into the charge storage layer in the corresponding memory cell transistor MT to raise the threshold voltage. On the other hand, to the charge storage layer in the memory cell transistor corresponding to the hit line BL(“1”), electrons are injected which are less in charge amount than electrons injected into the charge storage layer in the memory cell transistor MT corresponding to the bit line BL(“0”) and which are not sufficient to shift the threshold level. Thus, substantially no increase occurs in threshold voltage.

1.2.2 Details of the Write Operation

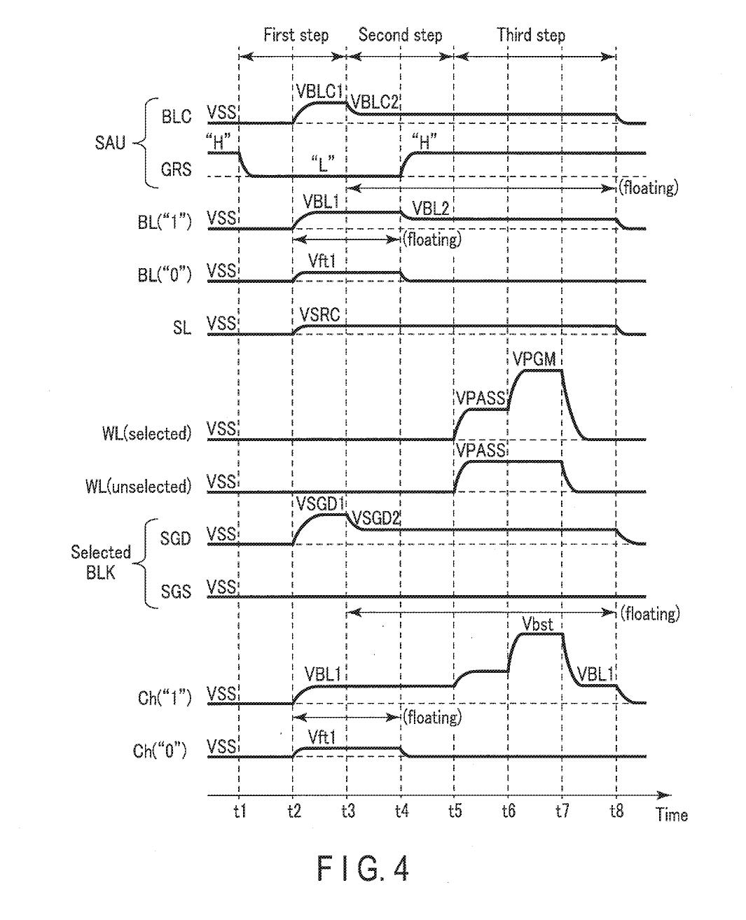

Now, the above-described data write operation will he described in detail using FIGS. 4 to 7.

<First Step>

As depicted in FIG. 4, first, at time t1, the sequencer 121 changes the signal GRS from the “H” level to the “L” level. Consequently, in the sense amplifier unit 130, the transistor 12 turned off.

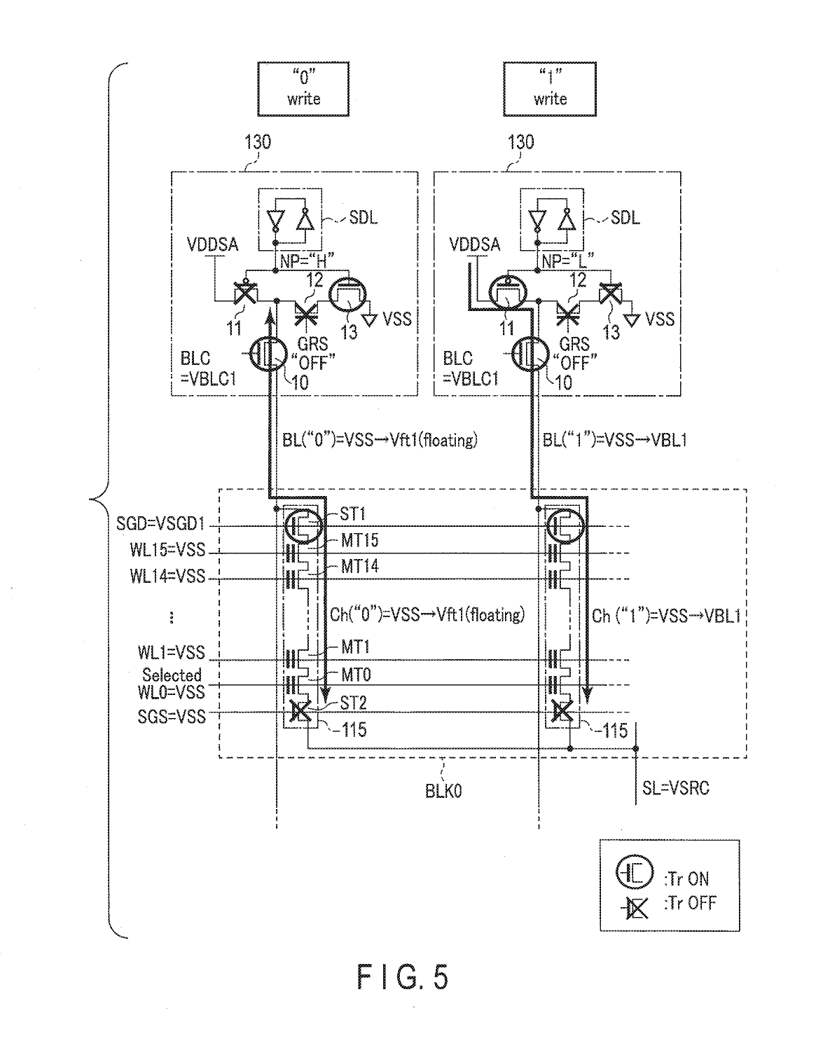

Now, a state at time t2 is illustrated in FIG. 5. As depicted in 4 and FIG. 5, the sequencer 121 sets the signal BLC to a voltage VBLC1. The voltage VBLC1 is a voltage which turns on all the transistors 10 corresponding to the write of “0” data and the write of “1” data. The row decoder 112 applies a voltage VSGD1 to the select gate line SGD for the selected block BLK to set the select transistor ST1 for the selected block BLK to the on state. The voltage SGD1 is a voltage which sets the select transistor ST1 to the on state regardless of the voltage of the bit line BL. A relation (VSGD1<Vt_st)>VBL1 is established. The threshold voltage of the select transistor ST1 is denoted by Vt_st. Consequently, the bit line BL(“0”) and the bit line BL(“1”) are electrically coupled to the channel Ch(“0”) and the channel Ch(“1”), respectively.

The row decoder 112 applies the voltage VSS to all the select gate lines SGS for the selected and unselected blocks BLK. Then, the source line driver 114 applies a voltage VSRC to the source line SL. The voltage VSRC is a positive voltage higher than the voltage VSS. The voltage VSRC sets the select transistor ST2 to a cutoff state and electrically uncouples the channel Ch(“0”) and the channel Ch(“1”) from the source line SL.

In this state, in the sense amplifier units 130 corresponding to the write of “1” data, the node NP is at the “L” level, and thus, the transistor 11 is set to the on state, whereas the transistor 13 is set to the off state. Thus, the voltage VDDSA is applied to the sense amplifier unit 130. Then, the sense amplifier unit 130 applies the voltage VBL1 clamped by the transistor 10 to the bit line BL(“1”). Between VBL1 and VBLC1, a relation VBL≦(VBLC1−Vt10) is satisfied. More specifically, (VBLC1−Vt10)>VBL1=VDDSA when a relation (VBLC1−Vt10)≧VDDSA is satisfied, and (VBCL1−Vt10)=VBL1 when a relation (VBCL1−Vt10)<VDDSA is satisfied.

On the other hand, in the sense amplifier units 130 corresponding to the write of “0” data, the node NP is at the “H” level, and thus, the transistor 11 is set to the off state, whereas the transistor 13 is set to the on state. However, the transistor 12 is in the off state, and thus, the sense amplifier unit 130 is prevented from applying the voltage VSS to the bit line BL(“0”). Therefore, the bit line BL(“0”) and the channel Ch(“0”) are set to the flowing state. When the voltage VBL1 is applied to the bit line BL(“1”), the voltage of the bit line BL(“0”) increases to the voltage Vft1 (≦VBL1) due to the coupling between the bit line BL(“0”) and the bit line BL(“1”).

The channels Ch(“0”) and Ch(“1”) are electrically coupled to the bit lines BL(“0”) and BL(“1”), respectively. Therefore, the voltages of the channels Ch(“0”) and Ch(“1”) increase to Vft1 and VBL1, respectively.

The “L” level of the signal GRS may be changed at time t2. That is, the change may be effected at the same timing as that of start of application of the voltage VBL1 to the bit line BL(“1”).

<Second Step>Now, at time t3, a second step is started. The sequencer 121 sets the signal BLC to a voltage VBLC2. The voltage VBLC2 is a voltage which is lower than the voltage VBLC1 and which sets the transistor 10 corresponding to the write of “1” data to the cutoff state, while setting the transistor 10 corresponding to the write of “0” data to the on state.

More specifically, at time t2, the voltage of the bit line BL(“1”) is at VBL1. Therefore, the sequencer 121 sets the voltage VBLC2 to a voltage meeting a relation (VBLC2−Vt10)<VBL1 in order to bring the transistor 10 corresponding to the write of “1” data into the cutoff state. The sequencer 121 further sets the voltage VBLC2 to a voltage meeting a relation (VBLC2−Vt10)>VSS in order to bring the transistor 10 corresponding to the write of “0” data into the on state to apply the voltage VSS to the bit line BL(“0”). Therefore, the voltage BLC2 is in a relation VBL1>(VBLC2−Vt10)>VSS.

The row decoder 112 applies the voltage VSGD2 to the select gate line SGD for the selected block BLK. The voltage VSGD2 is a voltage which is lower than the voltage VSGD1 and which sets the select transistor ST1 corresponding to the channel Ch(“1”) to the cutoff state, while setting the select transistor ST1 corresponding to the channel Ch(“0”) to the on state.

More specifically, the voltage of the bit line BL(“1”) is at VBL1 from time t4 to time t8 and at VBL2 (<VBL1) from time t4 to time t8 (the voltage VBL2 will be described below). Therefore, the row decoder 112 sets the voltage VSGD2 to a voltage meeting a relation (VSGD2−Vt_st<VBL2 (<VSL1) in order to keep the select transistor ST1 corresponding to the channel Ch(“1”) in the cutoff state from time t3 to time t8.

The sequencer 121 further sets the voltage VSGD2 to a voltage meeting a relation (VSGD2−V_st)>VSS in order to bring the select transistor ST1 corresponding to the channel Ch(“0”) into the on state to apply the voltage VSS. Therefore, the voltage VSGD2 is in a relation VBL2>(VSGD2−Vt_st)>VSS. This electrically uncouples the bit line BL(“1”) from the sense amplifier unit 130 and the channel Ch(“1”). Therefore, the bit line BL(“1”) and the channel Ch(“1”) are electrically uncoupled from each other and are each set to the floating state.

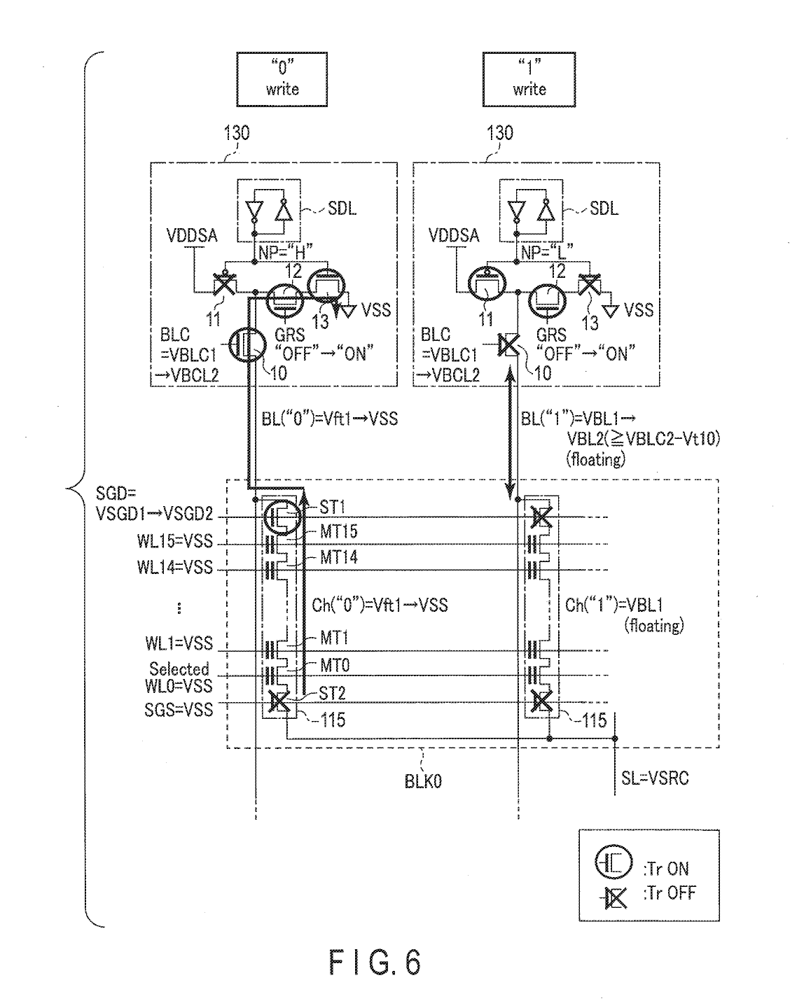

Now, a state at time t4 is illustrated in FIG. 6. As depicted in FIG. 4 and FIG. 6, the sequencer 121 changes the signal GRS from the “L” level to the “H” level. Consequently, in the sense amplifier unit 130, the transistor 12 is set to the on states Consequently, the sense amplifier unit 130 corresponding to the write of “0” data applies the voltage VSS to the bit line BL(“0”) (and the channel Ch(“0”)).

At this time, the voltage of the bit line BL(“1”) in the floating state decreases from VBL1 to VBL2 due to the coupling between the bit line BL(“1”) and the bit line BL(“0”). The voltage VBL2 is indicative of a voltage to which the voltage VBL1 has decreased due to the coupling. A lower limit value of the voltage VBL2 is equal to a clamp voltage “VBCL2−Vt10”. For example, when the voltage VBL2 of the bit line BL(“1”) decreases below the clamp voltage “VBCL2−Vt10” due to the coupling between the bit line BL(“1”) and the bit line BL(“0”), the transistor 10 in the cutoff state is set to the on state. Consequently, the clamp voltage “VBCL2−Vt10” from the sense amplifier unit 130 is applied to the bit line BL(“1”). Therefore, the voltage VBL2 is kept equal to or higher than the clamp voltage “VBCL2−Vt10” and is thus in a relation (VBCL2−Vt10)≦VBL2<VBL1.

The channel Ch(“1”) is in the floating state, and thus, the voltage of the channel Ch(“1”) is kept at VBL1.

<Third Step>

Then, at time t5, a third step is started. The row decoder 112 applies the voltage VPASS to the selected and unselected word lines WL. The voltage VPASS is a voltage which, during write, prevents miswriting to the unselected, memory cell transistors MT while setting the memory cell transistors MT to the on state regardless of the threshold of the memory cell transistors MT. Consequently, the voltage of the channel Ch(“1”) in the floating state increases due to the coupling between the channel Ch(“1”) and the word line WL.

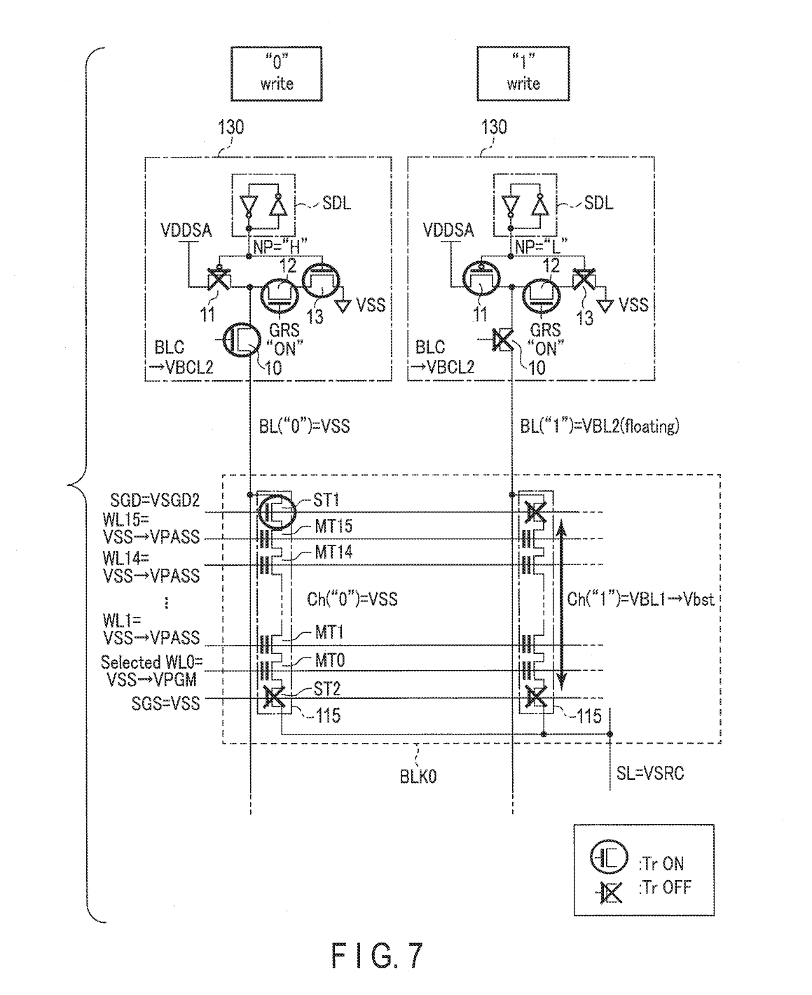

Now, a state at time t6 is illustrated in FIG. 7. As depicted in FIG. 4 and FIG. 7, the row decoder 112 applies the voltage VPGM to the selected word line WL. The voltage VPGM is a positive high voltage that allows charge to be injected into the charge storage layer, and has a relation VPGM>VPASS. Consequently, in the memory cell transistors MT which are coupled to the selected word line WL and to which “0” data is written, charge is injected into the charge storage layer. On the other hand, in the memory cell transistors MT which are coupled to the selected word line WL and to which “1” data is written, the voltage of the channel Ch(“1”) increases to Vbst (=“voltage VBL1”+“the value of voltage increase resulting from coupling”) due to coupling resulting from the voltage VPGM. Thus, substantially no charge is injected into the charge storage layer.

Subsequently, at time t8 and time t9, a recovery operation is performed to reset the voltages of the interconnects

### 1.3 Effects Related to the Present Embodiment

The configuration according to the present embodiment enables a reduction in power consumption. This effect will be described below.

During data write, the voltage VBL1 (<VSS) is applied to the bit line BL(“1”) and the channel Ch(“1”), and the voltage VSS is applied to the bit line BL(“0”) and the channel Ch(“0”). Subsequently, when the voltage VSGD2 is applied to the select gate line SGD, the select transistor ST1 corresponding to the channel Ch(“1”) is set to the cutoff state, and the channel Ch(“1”) is set to the floating state. In this state, when the VPGM is applied to the selected word line WL, the voltage of the channel Ch(“0”) increases to Vbst due to the coupling. Thus, substantially no charge is injected into the charge storage layer in the memory cell transistors MT to which “1” data is written. This is known as a self-boost technique.

In general, application, by the sense amplifier 113, of the voltage VBL1 to the bit line BL(“0”) (charging of the channel Ch(“1”)) is performed simultaneously with application, by the sense amplifier 113, of the voltage VSS to the bit line BL(“0”). In the semiconductor memory device, a plurality of bit lines BL is arranged in parallel in the same interconnect layer. Thus, a parasitic capacitance is generated between the bit line BL(“1”) and the bit line BL(“0”). In particular, when the bit line BL(“1”) and the bit line BL(“0”) are adjacent to each other, the capacitance between interconnects is large. Thus, in order to increase the voltage of the bit line BL(“1”) to VBL1, the bit line BL(“1”) need to be charged by an amount equal to the parasitic capacitance. This disadvantageously increases current consumption (power consumption).

A method for reducing the current consumption is to reduce the voltage VBL1. However, a reduced voltage VBL1 sets the select transistor ST1 corresponding to the channel Ch(“1”) to the on state rather than to the cutoff state, resulting in a high likelihood of miswriting. In other cases, a reduced Voltage VBL1 correspondingly reduces the voltage Vbst. This leads to an increased potential difference between the control gate of the memory cell transistor MT and the channel Ch, resulting in a high likelihood of injection of charge into the charge storage layer and thus of miswriting. Therefore, a reduced voltage VBL1 is likely to degrade reliability of the write operation.

In contrast, in the configuration according to the present embodiment, the application of the voltage VBL1 to the bit line BL(“1”) and the application of the voltage VSS to the bit line BL(“0”) are performed in different steps, and the bit lines BL to which no voltage is applied are kept in the floating state.

Consequently, when the voltage VBL1 is applied to the bit line BL(“1”), the adverse effect of the parasitic capacitance can be reduced, enabling a reduction in current consumption, that is, power consumption.

Moreover, in the configuration according to the present embodiment, when the voltage VSS is applied to the bit line BL(“0”), the select transistor ST1 corresponding to the write of “1” data is set to the cutoff state. Thus, the voltage of the channel Ch(“1”) can be restrained from decreasing below VBL1. Therefore, miswriting resulting from the reduced voltage VBL1 can be suppressed, allowing the reliability of the write operation to be restrained from being degraded.

Furthermore, in the configuration according to the present embodiment, when the voltage VBL1 is applied to the bit line BL(“1”), charging can be reduced by an amount equal to the parasitic capacitance. This enables a reduction in time needed to apply the voltage VBL1 to the bit line BL(“1”). Therefore, processing time can be shortened.

### 2. Second Embodiment

Now, a semiconductor memory device according to a second embodiment will be described. The second embodiment is different from the first embodiment in a timing to set the bit line BL(“0”) to the floating state when the voltage VBL1 is applied to the bit line BL(“1”). Only differences from the first embodiment will be described below.

2.1 Concept of the Write Operation

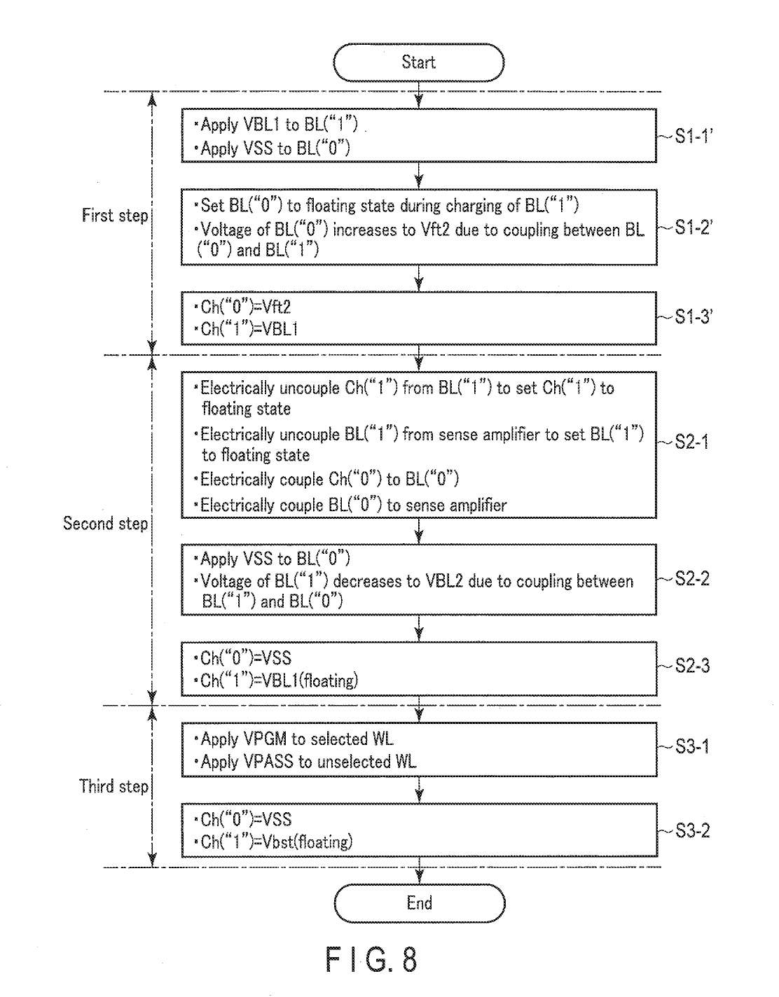

Now, the concept of the write operation in the present embodiment will be described using FIG. 8. FIG. 8 corresponds to FIG. 3 described in the first embodiment, and only differences from the first embodiment will be described below.

As depicted in FIG. 8, the write operation generally includes a first to a third steps as is the case with the first embodiment. Operations in the second and third steps are the same as the corresponding operations in FIG. 3.

<First Step>

In the first step in the present embodiment, the sense amplifier 113 applies the voltage VBL1 to the bit line BL(“1”), and before the voltage of the bit line BL(“1”) reaches VBL1 (during charging), sets the bit line BL(“0”to the floating state.

More specifically, first, the sense amplifier 113 applies the voltage VBL1 to the bit line BL(“1”) and applies the voltage VSS to the bit line BL(“0”) (step S1-1′).

Then, before the voltage of the bit line BL(“1”) reaches VBL1, that is, during charging, the sequencer 121 sets the bit line. BL(“0”) (and the channel Ch(“0”)) to the floating state (step S1-2′). When the bit line BL(“0”) is set to the floating state while the bit line BL(“1”) is being charged, the voltage of the bit line BL(“0”) increases (the voltage at this time is hereinafter referred to as referred to as “Vft2”)) due to the coupling during a period from the time point of the setting until the voltage of the bit line FL (“1”) reaches VBL1.

As a result, the voltages of the channels Ch(“0”) and Ch(“1”) increase to Vft2 and VBL1, respectively (step S1-3′).

2.2 Details of the Write Operation

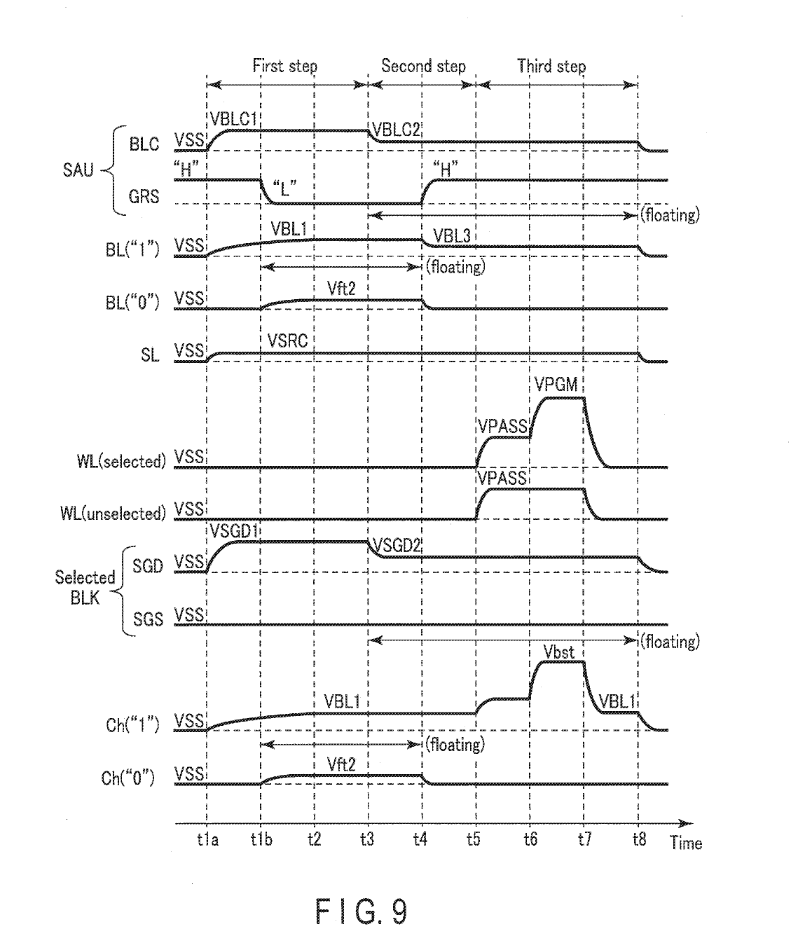

Now, the above-described data write operation will be described in detail using FIGS. 9 to 11. FIG. 9 corresponds to FIG. 4 described in the first embodiment. The third step (time t5 and later) is the same as the third step illustrated in FIG. 4. Only differences from FIG. 4 will be described below.

<First Step>

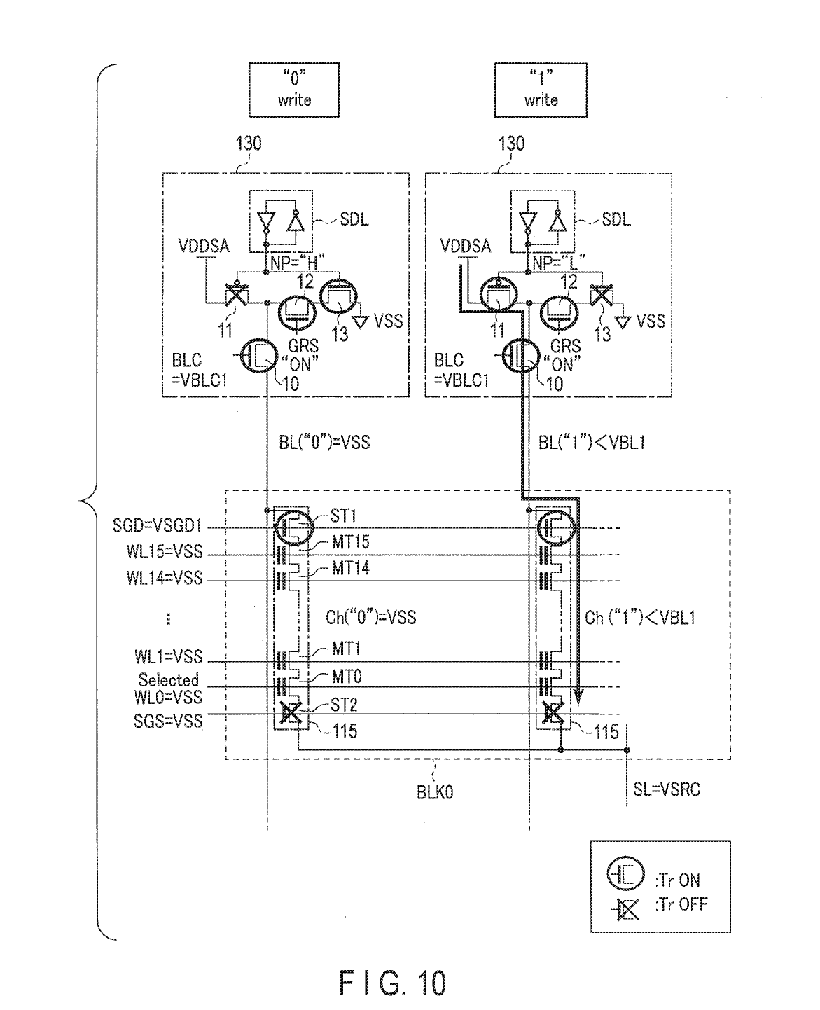

A state at time t1a is illustrated in FIG. 10. As depicted in FIG. 9 and FIG. 10, at time t1a, the sequencer 121 sets the signal BLC to the voltage VBLC1. Consequently, the sense amplifier 113 applies the voltage VSS to the bit line BL(“0”), and applies the voltage VBL1 to the bit line BL(“1”). In the present embodiment, the voltage of the bit line BL(“1”) is increased from the voltage VSS to the voltage VBL1 in a period from time t1a to time t2. The row decoder 112 applies the voltage VSGD1 to the select gate line SGD.

Then, at time t1b, the sequencer 121 changes the signal GRS from the “H” level to the “L” level. Consequently, the transistor 12 is set to the off state, and the bit line BL(“0”) is set to the floating state.

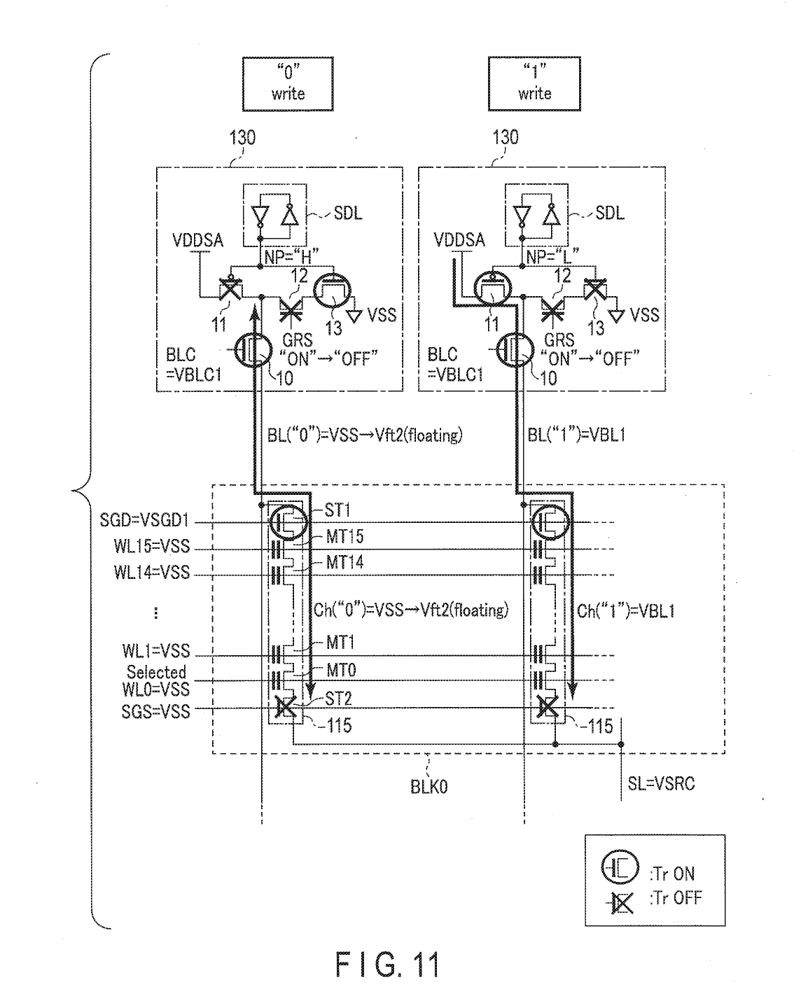

Now, a state between time t1b and time t2 is illustrated in FIG. 11. As depicted in FIG. 9 and FIG. 11, the voltage of the hit line BL(“0”) increases to Vft2 due to the coupling between the bit line BL(“0”) and the bit line BL(“1”). However, since the bit line BL(“0”) is set to the floating state during charging of the bit line BL(“1”), the amount of increase in voltage based on the coupling is smaller than that in the first embodiment. Consequently, a relation Vft1>Vft2 (>VSS) is established.

<Second Step>

At time t4, the voltage of the bit line BL(“1”) in the floating state decreases from VBL1 to VBL3 due to the coupling between the bit line BL(“1”) and the bit line BL(“0”). The voltage VBL3 is indicative of a voltage to which the voltage VBL1 has decreased due to the coupling. The voltage VBL3 is in a relation (VBL2−Vt10)≦VBL3<VBL1 similarly to the voltage VBL2 in the first embodiment. A relation Vft1>Vft2>VSS is established, and thus, the amount of decrease in voltage of the bit line BL(“1”) at time t4 is smaller than that in the first embodiment. Therefore, the voltages VBL3 and VBL2 are in a relation VBL2<VBL3<VBL1.

2. 3 Effects Related to the Present Embodiment

The configuration according to the present embodiment produces effects similar to the effects of the above-described first embodiment.

In the configuration according to the present embodiment, the bit line BL(“0”) is set to the floating state during charging of the bit line BL(“1”). This enables a reduction in the amount of increase in voltage of the bit line BL(“0”) based on the coupling, that is, a reduction in voltage Vft2. More specifically, the amount of increase in voltage of the bit line BL(“0”) can be controlled by controlling the period from the start of charging of the bit line BL(“1”) until the signal GRS is set to the “L” level.

3. Modifications

The semiconductor memory device according to the above-described embodiment includes: a first memory string (115) including a first memory cell transistor (MT); a second memory string (115) including a second memory cell transistor (MT); a word line (WL) coupled both to a gate of the first memory cell transistor and to a gate of the second memory cell transistor; a first bit line (BL(“1”) in FIG. 5) coupled to the first memory string; a second bit line (BL(“0”) in FIG. 5) coupled to the second memory string; a first sense amplifier (130 for “1” write in FIG. 5) capable of coupling the first bit line to one of a first power supply line to which a first voltage (VDDSA) is applied and a second power supply line to which a second voltage (VSS) lower than the first voltage is applied; and a second sense amplifier (130 for “0” write in FIG. 5) capable of coupling the second bit line to one of the first and second power supply lines. A write operation includes first and second steps. In the first step, when the second bit line is uncoupled from the first and second power supply lines, the first sense amplifier applies a third voltage (VBL1) higher than the second voltage and lower than or equal to the first voltage to the first bit line. In the second step, when the first bit line is uncoupled from the first and second power supply lines, the second sense amplifier applies the second voltage to the second bit line.

Application of any of the above-described embodiments allows provision of a semiconductor memory device that enables a reduction in power consumption. The embodiments are not limited to the above-described forms but various modifications may be made to the embodiments.

For example, the above-described embodiments may use a sense amplifier based on a voltage sensing scheme.

In the above-described embodiments, the transistor 12 in the sense amplifier unit 130 may be an n-channel MOS transistor or a p-channel MOS transistor.

Moreover, the “coupling” in the above-described embodiments includes the state of indirect coupling between objects with any other object, for example, a transistor or a resistor, interposed therebetween.

Several embodiments of the present invention have been described. The embodiments are presented as examples and are not intended to limit the scope of the present invention. The embodiments can be implemented in various other forms. Various omissions, replacements, or changes may be made to the embodiments without departing from the spirits of the invention. These embodiments and modifications thereof are included in the scope and spirits of the invention.

The embodiments related to the present invention may be as described below. For example, when the memory cell transistor MT is assumed to be able to hold 2 bits (four values) and threshold levels used while one of the four values is held are assumed to include an E level (erase level), an A level, a B level, and a C level in order of increasing level, the embodiments are as follows.

(1) In a read operation, a voltage applied to a word line selected for a read operation at the A level is, for example, between 0 V and 0.55 V. The voltage is not limited to this range but may be between 0.1 V and 0.24 V, between 0.21 V and 0.31 V, between 0.31 V and 0.4 V, between 0.4 V and 0.5 V, or between 0.5 V and 0.55 V.

A voltage applied to a word line selected for a read operation at the B level is, for example, between 1.5 V and 2.3 V. The voltage is not limited to this range but may be between 1.65 V and 1.8 V, between 1.8 V and 1.95 V, between 1.95 V and 2.1 V, or between 2.1 V and 2.3 V.

A voltage applied to a word line selected for a read operation at the C level is, for example, between 3.0 V and 4.0 V. The voltage is not limited to this range but may be between 3.0 V and 3.2 V, between 3.2 V and 3.4 V, between 3.4 V and 3.5 V, between 3.5 V and 3.6 V, or between 3.6 V and 4.0 V.

The time (tR) needed for the read operation may be, for example, between 25 μs and 38 μs, between 38 μs and 70 μs, or between 70 μs and 80 μs.

(2) The write operation includes a program operation and a verify operation as described above. In the write operation, a voltage applied first to a word line selected during the program operation is, for example, between 13.7 V and 14.3 V. The voltage is not limited to this range but may be, for example, between 13.7 V and 14.0 V or between 14.0 V and 14.6 V.

The voltage applied first to the word line selected when the write operation is performed on odd-numbered word lines may differ from the voltage applied first to the word line selected when the write operation is performed on even-numbered word lines.

A step-up voltage used when the program operation is based on an ISPP scheme (Incremental Step Pulse Program) may be, for example, approximately 0.5 V.

The voltage applied to the unselected word lines may be, for example, between 6.0 V and 7.3 V. The present invention is not limited to this case, and the voltage may be, for example, between 7.3 V and 8.4 V or 6.0 V or lower.

The applied pass voltage may be varied depending on whether the unselected word line is an odd-numbered word line or an even-numbered word line.

The time (tProg) needed for the write operation may be, for example, between 1700 μs and 1800 μs, between 1800 μs and 1900 μs, or between 1900 μs and 2000 μs.

(3) For an erase operation, a voltage applied first to a well which is formed in an upper part of the semiconductor substrate and over which the memory cell is arranged is, for example, between 12 V and 13.6 V. The present invention is not limited to this case, and the voltage may be, for example, between 13.6 V and 14.8 V, between 14.8 V and 19.0 V, between 19.0 V and 19.8 V, or between 19.8 V and 21 V.

The time (tErase) needed for the erase operation may be, for example, between 3000 μs and 4000 μs, between 4000 μs and 5000 μs, or between 4000 μs and 9000 μs.

(4) The memory cell has a charge storage layer arranged on the semiconductor substrate (silicon substrate) via a tunnel, insulating film with a film thickness of 4 to 10 nm. The charge storage layer may have a stack structure including an insulating film such as SiN or SiON having a film thickness of 2 to 3 nm and a polysilicon film having a film thickness of 3 to 8 nm. A metal such as Ru may be added to the polysilicon. An insulator is provided on the charge storage layer. The insulation film has, for example, a silicon oxide film having a film thickness of 4 to 10 nm and sandwiched between an underlayer high-k film having a film thickness of 3 to 10 nm and an upper-layer hi k film having a film thickness of 3 to 10 nm. The high-k film may be HfO. The film thickness of silicon oxide film may be larger than that of the high-k film. A control electrode having a thickness of 30 nm to 70 nm is formed on the insulation film via a material having a film thickness of 3 to 10 nm and used to adjust a work function. The material for adjustment of a work function is a metal oxide film such as TaO or a metal nitride film such as TaN. For the control electrode, W or the like may be used.

An air gap may be formed between memory cells.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first memory string including a first memory cell transistor;
a second memory string including second memory cell transistor;
a word line coupled both to a gate of the first memory cell transistor and to a gate of the second memory cell transistor;
a first bit line coupled to the first memory string;
a second bit line coupled to the second memory string;
a first sense amplifier capable of coupling the first bit line to one of a first power supply line to which a first voltage is applied and a second power supply line to which a second voltage lower than the first voltage is applied; and
a second sense amplifier capable of coupling the second bit line to one of the first and second power supply lines,
wherein a write operation includes first and second steps,
in the first step, when the second bit line is uncoupled from the first and second power supply lines, the first sense amplifier applies a third voltage higher than the second voltage and lower than or equal to the first voltage to the first bit line, and
in the second step, when the first bit line is uncoupled from the first and second power supply lines, the second sense amplifier applies the second voltage to the second bit line.

2. The device according claim 1, wherein
the first sense amplifier includes:
a first transistor including a first terminal coupled to the first bit line and a second terminal;
a second transistor including a first terminal coupled to the first power supply line and a second terminal coupled to the second terminal of the first transistor;
a third transistor including a first terminal coupled to the second terminal of the first transistor and a second terminal; and
a fourth transistor including a first terminal coupled to the second power supply line and a second terminal coupled to the second terminal of the third transistor,
the second sense amplifier includes:
a fifth transistor including a first terminal coupled to the second bit line and a second terminal;
a sixth transistor including a first terminal coupled to the first power supply line and a second terminal coupled to the second terminal of the fifth transistor;
a seventh transistor including a first terminal coupled to the second terminal of the fifth transistor and a second terminal; and
an eighth transistor including a first terminal coupled to the second power supply line and a second terminal coupled to the second terminal of the seventh transistor,
in a write operation, a signal at a first logic level is input to gates of the second and fourth transistors and a signal at a second logic level is input to gates of the sixth and eighth transistors,
in the first step, a fourth voltage higher than the third voltage is applied to gates of the first and fifth transistors, and the signal at the first logic level is input to gates of the third and seventh transistors, and
in the second step, a fifth voltage higher than the second voltage and lower than the fourth voltage is applied to the gates of the first and fifth transistors, and the signal at the second logic is input to the gates of the third and seventh transistors.

3. The device according to claim 1, wherein
the first memory string further includes a first select transistor including a first terminal coupled to the first bit line and a second terminal coupled to the first memory cell transistor,
the second memory string further includes a first select transistor including a first terminal coupled to the second bit line and a second terminal coupled to the second memory cell transistor,
gates of the first and second select transistors are both coupled to a select gate line,
in the first step, a sixth voltage higher than the third voltage is applied to the select gate line, and
in the second step, a seventh voltage higher than the second voltage and lower than the sixth voltage is applied to the select gate line.

4. The device according to claim 2, wherein
the second and sixth transistors are p-channel MOS transistors and are set to an on state according to the signal at the first logic level, and
the third, fourth, seventh, and eighth transistors are n-channel MOS transistors and are set to an on state according to the signal at the second logic level.

5. The device according to claim 1, wherein
in the first step, the third voltage is applied to a channel for the first memory string through the first bit line, and
in the second step, the second voltage is applied to a channel for the second memory string through the second bit line.

6. The device according to claim 1, further comprising:
a source line coupled both to the first and second memory strings,
wherein the first memory string further includes a third select transistor including a first terminal coupled to the source line and a second terminal coupled to the first memory cell transistor,
the second memory string further includes a fourth select transistor including a first terminal coupled to the source line and a second terminal coupled to the second memory cell transistor, and
in the write operation, the second voltage is applied to gates of the third and fourth select transistors.

7. The device according to claim 1, wherein
after the second step, an eighth voltage higher than the first voltage is applied to the word line.

8. The device according to claim 2, wherein
in the first step, the first and fifth transistors are set to an on state, and
in the second step, the first transistor is set to an off state, and the fifth transistor is set to the on state.

9. The device according to claim 1, wherein
each of the first and second memory cell transistors includes a charge storage layer and stores data in a nonvolatile manner.

10. The device according to claim 3, wherein
in the first step, the first and second select transistors are set to an on state, and
in the second step, the first select transistor is set to an off state, and the second select transistor is set to the on state.

11. A semiconductor memory device comprising:
a first memory string including a first memory cell transistor;
a second memory string including a second memory cell transistor;
a word line coupled both to a gate of the first memory cell transistor and to a gate of the second memory cell transistor;
a first bit line coupled to the first memory string;
a second bit line coupled to the second memory string;
a first sense amplifier capable of coupling the first bit line to one of a first power supply line to which a first voltage is applied and a second power supply line to which a second voltage lower than the first voltage is applied; and
a second sense amplifier capable of coupling the second bit line to one of the first and second power supply lines,
wherein a write operation includes first and second steps,
in the first step, when the second bit line is coupled to the second power supply line, the first sense amplifier starts the application of the third voltage higher than the second voltage and lower than or equal to the first voltage to the first bit line,
before a voltage of the first bit line reaches the third voltage, the second bit line is uncoupled from the second power supply line, and
in the second step, when the first bit line is uncoupled from the first and second power supply lines, the second sense amplifier applies the second voltage to the second bit line.

12. The device according to claim 11, wherein
the first sense amplifier includes:
a first transistor including a first terminal coupled to the first bit line and a second terminal;
a second transistor including a first terminal coupled to the first power supply line and a second terminal coupled to the second terminal of the first transistor;
a third transistor including a first terminal coupled to the second terminal of the first transistor and a second terminal; and
a fourth transistor including a first terminal coupled to the second power supply line and a second terminal coupled to the second terminal of the third transistor,
the second sense amplifier includes:
a fifth transistor including a first terminal coupled to the second hit line and a second terminal;
a sixth transistor including a first terminal coupled to the first power supply line and a second terminal coupled to the second terminal of the fifth transistor;
a seventh transistor including a first terminal coupled to the second terminal of the fifth transistor and a second terminal; and
an eighth transistor including a first terminal coupled to the second power supply line and a second terminal coupled to the second terminal of the seventh transistor,
in a write operation, a signal at a first logic level is input to gates of the second and fourth transistors and a signal at a second logic level is input to gates of the sixth and eighth transistors,
in the first step, when a fourth voltage higher than the third voltage is applied to gates of the first and fifth transistors and the signal at the second logic level is input to gates of the third and seventh transistors, application of the third voltage to the first bit line and application of the second voltage to the second bit line are started,
before a voltage of the first bit line reaches the third voltage, the signal at the first logic level is input to the gates of the third and seventh transistors, and
in the second step, a fifth voltage lower than the fourth voltage is applied to the gates of the first and fifth transistors, and the signal at the second logic level is input to the gates of the third and seventh transistors.

13. The device according to claim 11, wherein
the first memory string further includes a first select transistor including a first terminal coupled to the first bit line and a second terminal coupled to the first memory cell transistor,
the second memory string further includes a second select transistor including a first terminal coupled to the second bit line and a second terminal coupled to the second memory cell transistor,
gates of the first and second select transistors are both coupled to a select gate line, and
in the first and second steps, a sixth voltage higher than the third voltage is applied to the select gate line.

14. The device according to claim 12, wherein
the second and sixth transistors are p-channel MOS transistors and are set to an on state according to the signal at the first logic level, and
the third, fourth, seventh, and eighth transistors are n-channel MOS transistors and are set to an on state according to the signal at the second logic level.

15. The device according to claim 11, wherein
in the first steps, the third voltage is applied to a channel for the first memory string through the first bit. line,
before the voltage of the first bit line reaches the third voltage, the second voltage is applied to a channel for the second memory string through the second bit line, and
in the second step, the second voltage is applied to a channel for the second memory string through the second bit line.

16. The device according to claim 11 further comprising:
a source line coupled both to the first and second memory strings,
wherein the first memory string further includes a third select transistor including a first terminal coupled to the source line and a second terminal coupled to the first memory cell transistor,
the second memory string further includes a fourth select transistor including a first terminal coupled to the source line and a second terminal coupled to the second memory cell transistor, and
in the write operation, the second voltage is applied to gates of the third and fourth select transistors.

17. The device according to claim 11, wherein
after the second step, a seventh voltage higher than the first voltage is applied to the word line.

18. The device according to claim 12, wherein
in the first and second steps, the first and second select; transistors are set to an on state.

19. A semiconductor memory device comprising:
a first memory string including a first memory cell transistor;
a second memory string including a second memory cell transistor;
a word line coupled both to a gate of the first memory cell transistor and to a gate of the second memory cell transistor;
a first bit line coupled to the first memory string; and
a second bit line coupled to the second memory string,
wherein, in a write operation, when a first voltage is applied to the first bit line, the second bit line and the second memory string are electrically coupled together and set to a floating state, and
when a second voltage is applied to the second bit line and the second memory string, the first bit line and the first memory string are electrically uncoupled from each other and are each set to the floating state.

20. The device according to claim 19, wherein
when the second voltage is applied to the second memory string and first memory string is set to the floating state, a third voltage higher than the first voltage is applied to the word line.
